(19) United States
(12) Patent Application Publication
(10) Pub. No.: US 2009/0252202 A1
(43) Pub. Date: Oct. 8, 2009

(54) METHOD AND APPARATUS FOR ENHANCED DECODING IN MULTI-BAND ULTRA-WIDEBAND COMMUNICATIONS

(75) Inventor: Vasanth R. Gaddam, Tarrytown, NY (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/721,193

(22) PCT Filed: Dec. 8, 2005
(86) PCT No.: PCT/IB05/54141

§ 371 Date: Jun. 8, 2007

(51) Int. Cl. H04B 1/707; H03K 7/04; H04B 1/00

(52) U.S. Cl. 375/150; 375/239; 375/130; 375/E01.002

(57) ABSTRACT

A data transmission and reception method includes transmitting a plurality of position data bits and a amplitude bits with each of the pulses. The method also includes decoding the position bits and the amplitude bits. An ultra-wideband (UWB) system is also described.

Ultra wideband (UWB) communications involve transmission of signals that occupy a large bandwidth. In a UWB system, a modulated signal is either transmitted as a base-band pulse (carrier-free transmission) or is converted (mixed) upward in frequency to a certain carrier frequency. Many UWB applications have been limited to radar and military communications. However, because of the potential for use of UWB technology in high data-rate, short range communications, the Federal Communications Commission (FCC) has provided the frequency band from 3.1 GHz to 10.6 GHz for unlicensed devices.

UWB communication systems transmit short-duration pulses of data over the transmission range referenced. As can be appreciated, because of the relatively short duration of the pulse in the time domain, the number of frequency components is quite large. This correlates to a relatively wide bandwidth signal. Accordingly, a properly designed UWB system provides transmission of a significant amount of data in relatively short time, making UWB systems rather attractive for high data-rate applications.

While potentially beneficial, known UWB systems have certain challenges. For example, in one type of UWB system, a short duration pulse (usually on the order of psec) is transmitted at the desired rate. This pulse is modulated by the encoded data. If the pulse repetition rate is small, the inter-pulse distance is very large. This is advantageous in multi-path channels, since the receiver can resolve the different multipath components. However, in order to achieve high data rates, the repetition rate has to be increased. Due to implementation constraints, the rate cannot be increased beyond a limit.

Moreover, in known single band UWB systems, since the signal occupies a large bandwidth, any in-band interference has to be mitigated by using notch filters. This will increase the cost of the device. In order to overcome some of the disadvantages of the single-band system, recently multi-band systems have been proposed.

In multi-band pulsed UWB systems, the data are modulated on to pulses and then transmitted in different frequency bands that are interleaved over time. Each of these bands is approximately 500 MHz wide and therefore up to 14 bands can be used in the allocated spectrum. Compared to a single band system, the multi-band system provides flexibility in terms of adding/dropping bands based on interference scenarios and data-rate requirements.

The use of multi-band pulse UWB systems is beneficial to the transmission of short-duration pulses, providing a relatively wide bandwidth over which the data can be sent. However, as the transmission rate increases, the possibility for transmission errors also increases. In order to reduce the transmission errors in the transmission of data, data coding and decoding schemes have been proposed. These coding and decoding schemes, often referred to as forward error correction (FEC) schemes, improve the channel capacity and the reliability of the data transmissions. The FEC schemes provide redundant information to the transmitted signal. This is known as channel coding.

One known channel coding technology is convolutional encoding. Convolutional encoding operates on serial data, coding the data for transmission. At the receiver, methods are used to decode the received coded data to recover the information sequence. One such decoding scheme is Viterbi decoding.

While known encoding methods are beneficial, there is a need to provide greater reliability with respect to decoded data.

A data transmission and reception method includes transmitting a plurality of position data bits and a plurality of amplitude data bits with each of the position data bits; and

decoding the position data bits and the amplitude data bits.

An ultra-wide band (UWB) system (400), comprising:

a matched filter/correlator (403), which provides information on a plurality of position data bits and information on a plurality of amplitude data bits to a demapper/convolutional decoder (406), which decodes the position data bits and the amplitude data bits.

### BRIEF DESCRIPTION OF THE DRAWINGS

The example embodiments are best understood from the following detailed description when read with the accompanying drawing figures. It is emphasized that the various features are not necessarily drawn to scale, and in fact may be arbitrarily increased or decreased for clarity of discussion.

FIG. 1 is a conceptual representation of a Time-Frequency interleaved 5-band UWB system in accordance with an example embodiment.

FIG. 2 is a timing diagram showing pulse transmission, repetition and duration in accordance with an example embodiment.

FIG. 3 is a mapping table for use in a coding/decoding method in accordance with an example embodiment.

FIG. 4 is a schematic block diagram of a multi-band UWB receiver in accordance with an example embodiment.

FIG. 5 is a graphical representation of a received data after demodulation and correlation at a receiver in accordance with an example embodiment.

FIG. 6 is a schematic diagram of a UWB system in accordance with an example embodiment.

### DETAILED DESCRIPTION

In the following detailed description, for purposes of explanation and not limitation, example embodiments disclosing specific details are set forth in order to provide a thorough understanding of the example embodiments.

However, upon review of this disclosure, other embodiments that do not depart from the concepts of the described example embodiments will be apparent to one having ordinary skill. Moreover, descriptions of well-known devices, elements, methods and systems may be omitted so as to not obscure the description of the example embodiments. Nonetheless, such devices, methods, systems and protocols that are within the purview of one of ordinary skill in the art may be used in accordance with the example embodiments. Finally, wherever practical, like reference numerals refer to like features.

Briefly, the example embodiments relate to methods and apparati for forward error correction in communication systems. The forward error correction methods include the use of the amplitude data bits or sign bits in the trace-back operation to improve the reliability of the transmitted data by an improvement in the bit error rate (BER).

Illustratively, a convolutional coder encodes one bit into two bits. The encoded bits along with one amplitude bit are used to modulate a pulse.

A receiver demodulates the pulse and inputs the information about the position bits and the sign bit to a decoder. In this manner the reliability of the data is improved, with an increase in the gain on the order of approximately 1.5 dB to approximately 2.0 dB compared to coding/decoding methods that use information of the position bits only.

It is noted that the example embodiments are described in connection with UWB wireless communications and associated elements. It is emphasized that the application of the methods and apparati of the example embodiments are merely for illustrative purposes. Clearly, the methods and apparati of the example embodiments may be implemented in other communication applications. Moreover, the modulation and coding techniques described are also illustrative of the example embodiments. For example, the coding is illustratively a Viterbi-type coding/modulation. However, other trellis coding modulation (TCM) may be implemented. Of course, other coding modulation techniques will be readily apparent to one of ordinary skill in the art. Such techniques may be implemented in keeping with the example embodiments.

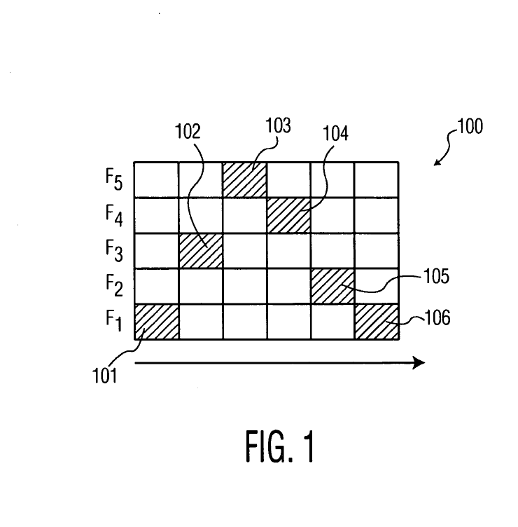

FIG. 1 is a conceptual view of a time-frequency interleaved multi-band UWB system 100 in accordance with an example embodiment. In this example embodiment, the data modulated pulses are transmitted in frequency band F₁ 101 during a first time slot. Similarly, in a second time slot, modulated pulses are transmitted in band F₃ 102; during a third time slot, modulated pulses are transmitted in band F₅ 103; during a fourth time slot, modulated pulses are transmitted in band F₄ 104; and during a fifth time slot, modulated pulses are transmitted in band F₂. As can be seen, the process repeats with another modulated pulse transmission in band F₁ 106.

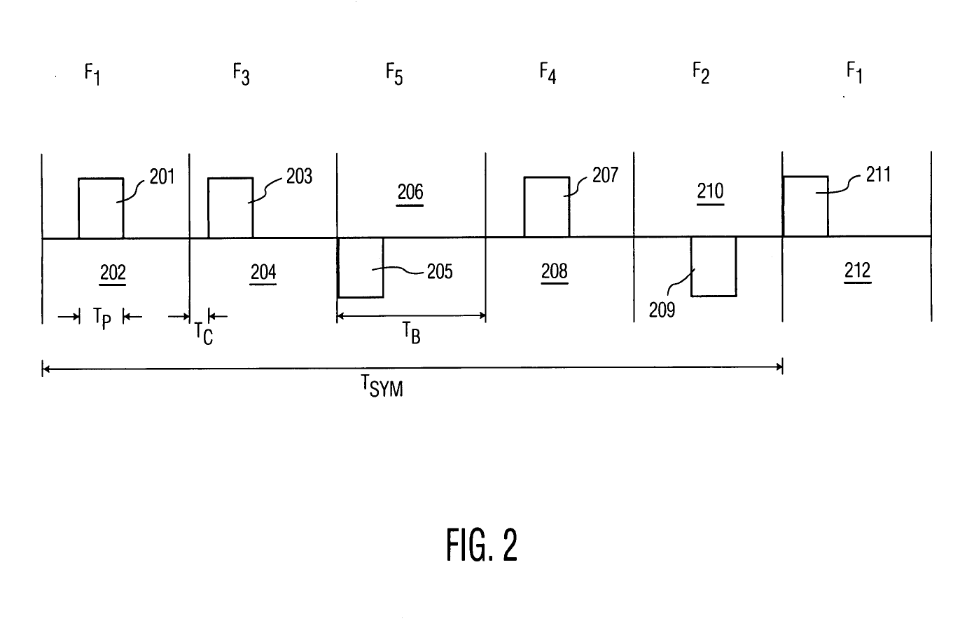

As referenced previously, it is useful to increase the pulse repetition rate in order to increase the data rate of the system. In addition, it may be useful to increase the data rate by increasing the number of bits transmitted per pulse. This can be achieved by using amplitude modulation and/or position modulation techniques, which are well known in the art. A system that combines both pulse amplitude modulation (PAM) and pulse position modulation (PPM) in a multi-band UWB system is highly desirable for increasing the throughput of the channel. In the PPM-PAM system, some of the bits are used to modulate the position of the pulse, while the remaining bits are used to modulate the amplitude of the pulse. This is understood from a review of FIG. 2, which is a timing diagram of a 4 PPM/Binary Phase Shift Keying (BPSK) modulated UWB system.

In a BPSK modulated pulse, each pulse carries only one amplitude bit. Therefore, the sign of the amplitude gives the information about the bit. Accordingly, the amplitude bit of a BPSK modulated pulse may be referred to as a sign bit. Contrastingly, in a 4-PAM modulated pulse each pulse carries two amplitude bits. This will result in the pulse's taking four levels. So, at the receiver, the amplitude must be determined in order to determine the two transmitted bits.

The first frequency band F₁ modulated pulse 201 is transmitted during a first time slot 202. The pulse 201 has a pulse duration Tₚ as shown. Likewise, a third frequency band F₃ modulated pulse 203 is transmitted in a second time slot 204; a fifth frequency band F₅ modulated pulse 205 is transmitted in a third time slot 206; a fourth frequency band F₄ modulated pulse 207 is transmitted in a fourth time slot 204; and a second frequency band F₂ modulated pulse 208 is transmitted in a fifth time slot 209; and the process repeats with a first frequency band F₁ modulated pulse 211 being transmitted in a first slot of the sequence.

Based on the design requirements, the PPM shift T_{c} could be less than the pulse duration Tₚ or greater than the pulse duration. The PPM shift affects the performance of the receiver. For example, if a correlation based receiver is used to demodulate the data of the pulses 201, 203, 205, 207, 209 and 211, the performance of the amplitude bits and the PPM bits depend on the shift. If the shift duration is greater than the pulse duration, then the performance of the PPM bits is better than the performance of the amplitude bits. If the shift duration is less than the pulse duration, then the performance of the amplitude bits is better than the performance of the PPM bits.

At the receiver, the correlator calculates the correlation of the received pulse with all the possible positions. If there is no overlap among different pulse positions (i.e. the shift duration is greater than pulse duration), then the correlation values are distinct (assuming a clean channel). The correlation corresponding to the position of the pulse where it was transmitted will be substantially at a maximum, while the rest of the correlation values will be relatively small.

However, when there is an overlap among different pulse positions, the correlation at any pulse position has some contribution from the neighboring positions. Therefore, the position information in this case is not as reliable as the one in the other case.

For amplitude bits, the integration period in the case of shift duration greater than pulse width is more than the other case. This will result in the addition of more noise and therefore the performance is slightly worse than the other case.

Usually, the PPM shift duration is less than the pulse duration to account for the multi-path interference. As mentioned above, in this example the amplitude bits are more robust than the position bits. In order to improve the performance of the position bits and to bring their performance on par with the performance of the amplitude bits, channel coding can be used on PPM bits.

As referenced previously, one method of coding channels is using a convolutional encoder or similar trellis based coding scheme. In the example embodiments described herein, the modulation scheme used in conjunction with trellis coding/decoding is a four-PPM/BPSK system, which is an example of the PPM-PAM modulation system. It is again emphasized that this is merely illustrative and that other types and combinations of amplitude modulation and m-ary PPM modulation schemes may be used.

The 4-PPM/BPSK system splits the information bits as the PPM bits and the amplitude/sign bits. The PPM bits are then encoded using a convolutional encoder. As is known, convolutional encoders are usually described in terms of two parameters: the code rate and the constraint length. The code length, k/n, is expressed as a ratio of the number of bits into the convolutional encoder to the number of channel signals output by the encoder in a given cycle. For example, a convolutional encoder that receives 1 bit and outputs 2 channel signals is referred to as a rate one-half (½) convolutional coder.

The constraint length parameter, K, denotes the length of the convolutional encoder. To wit, the constraint length parameter denotes how many stages are available feed to the combinatorial logic that produces the output symbols. Finally, a parameter (m) that is closely related to K is the number of encoder cycles an input bit is retained and used for encoding after it first appears at the input of the encoder. This is often referred to as the memory of the encoder.

In the present example embodiment, the convolutional encoder is a rate-1/2 convolutional coder. The constraint length of the coder can be selected based on the performance requirements. One way of specifying the performance of a coder is by bit-error rate (BER) for a given signal to noise ratio (SNR). For example, if one encoder gives a BER=0.0001 at SNR=5 dB while another gives a BER of 0.001 at the same SNR, then the first coder is beneficial from performance point of view. But this performance usually comes at the cost of additional complexity/hardware, to name only some factors affecting the cost. Thus, many considerations are reviewed when an encoder is selected

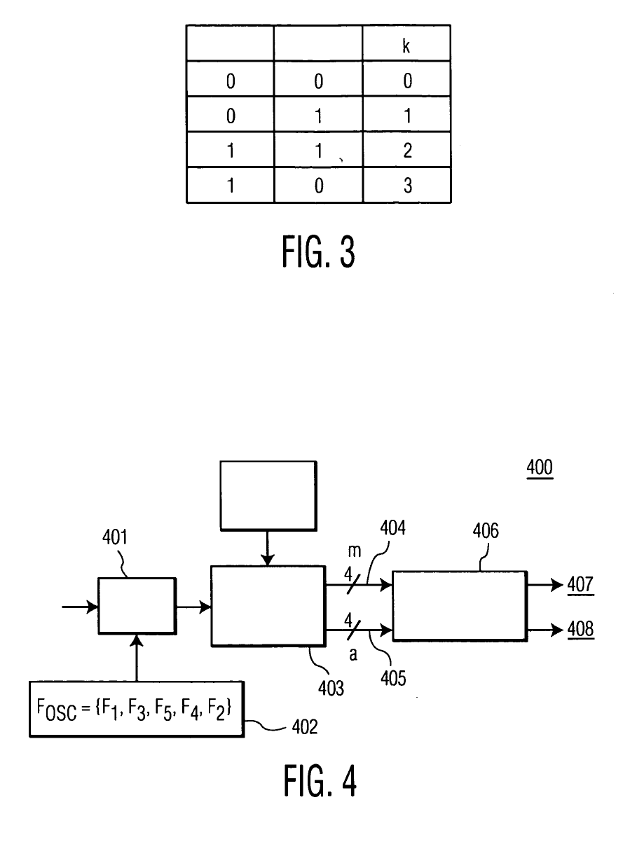

The output of the convolutional coder is then passed through a Gray coder that maps the two bits to one of the four positions as shown in Table 1 of FIG. 3. This mapping may be understood from a review of FIGS. 2 and 3. For example, consider the first time slot 202. The position bit is coded into two coded bits ‘11’ which when Gray coded will result in ‘2’ in Table 1. Therefore, the pulse will be transmitted in position 2. Also, the sign/amplitude bit in this case is 1; therefore a pulse with positive amplitude is transmitted.

The position determines the relative shift in the position of the pulse. The output of the mapper is then sent to a PPM modulator, where it is used for shifting the position of the pulse. The pulse is then multiplied by the BPSK modulated sign bit. The effective rate of this system is 2/3, since two information bits are coded into three data bits: two position bits (b₀, b₁) and one sign or amplitude bit (b₂).

The output of the PPM modulator is mixed up to the specified frequency and transmitted using well-known transmission techniques and devices. The order of the frequency bands is pre-determined (e.g., the order of FIG. 1) and is not changed for the duration of the transmission. The transmitted signal can be represented as:

$$s ( t ) = {\sum }_{n = - ∞}^{∞} {a}_{n} p ( t - {nT}_{b} - {c}_{n} {T}_{c} ) cos ( {w}_{o} t ) \qquad ( 1 )$$

where: p(t) is the basic pulse; T_{b} is the pulse repetition period; T_{c} is the minimum shift duration; aₙ is derived from the sign bit (aₙ=1 if sign bit=1, aₙ=−1 if sign bit=0); and cₙ is the amount of shift and is derived from the coded bits. (Table 1 of FIG. 3).

For 4-PPM modulation cₙ=0, 1, 2, or 3 and ŝ₀ is the carrier frequency which is changed every T_{b} seconds. The carrier frequency is selected from the subset {F₁, F₃, F₅, F₂ and F₄}. One set of carrier frequencies is given by fₙ=3.5×10⁹+500×10⁶*(n−1) .

The transmitted pulses are received at a receiver 400 in accordance with an illustrative embodiment shown in FIG. 4. The receiver 400 includes a mixer 401, which is coupled to a local oscillator 402 that inputs sequentially one of F₁-F₅, depending on the frequency of the pulse. The output of the mixer 401 is input to a matched filter/correlator 403. The correlator 403 outputs correlation values mₖ 404 and amplitude/sign information aₖ 405 are input to a demapper/convolutional decoder 406. The matched filter/correlator 402 correlates the received signal with the shifted versions of the pulse template, providing the correlation values:

$${m}_{k} ( n ) = {\int }_{0}^{{T}_{p}} {a}_{n} p ( t - {nT}_{b} - {c}_{n} {T}_{c} ) p ( t - {nT}_{b} - {kT}_{c} ) \qquad ( 2 )$$

where k=0, 1, 2, and 3 for the 4-PPM/BPSK system of the presently described example embodiments. Because the rest of the description of the example embodiments is independent of n, mₖ is used instead of mₖ(n).

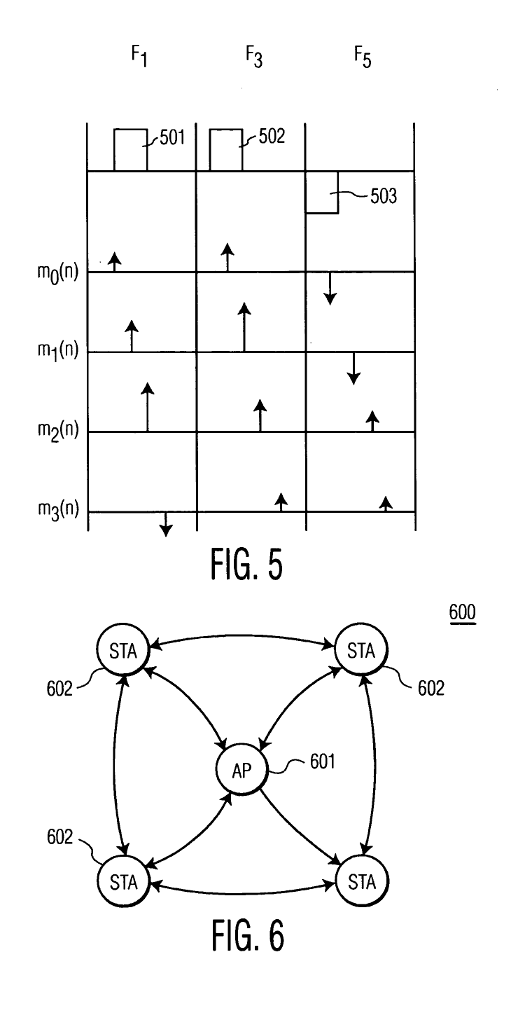

FIG. 5 shows the output 500 of the correlator 403 for the illustrative input pulses with the coding shown. For example, a first frequency band modulated pulse 501 includes coded bits 10 and amplitude/sign bit 1; a third frequency band pulse 502 has coded bits 01 and amplitude/sign bit 1; and a fifth frequency band modulated pulse 503 has coded bits 00 and amplitude/sign bit 0. From the Equation 2, the correlator 403 calculates m₀ through m₃ with the respective results shown in FIG. 5.

The position of the pulse and the sign bit of the transmitted pulse are derived from mₖ as shown in Equations 3 and 4 respectively.

$$\begin{matrix}pos = arg {max}_{[ k ]} ( abs ( {m}_{k} ) ) & ( 3 ) \\ bpsk\_bit = sign ( {m}_{pos} ) & ( 4 )\end{matrix}$$

The demapper of block 406 converts the position signal into two data bits. The convolutional decoder of block 406 uses Viterbi algorithm, or similar trellis decoding method to decode the PPM (position) bit from the two bit input data. As referenced previously, the performance of this decoding scheme is less than optimal. The performance is improved by the methods and apparati of example embodiments, which include soft metrics for the Viterbi decoder. These example embodiments are described presently.

In accordance with example embodiments, a method and apparatus for improving the performance of the PPM bit and the amplitude bit(s) incorporates the use of soft metrics and incorporate the sign bit in a trellis trace-back sequence. In the above described coding schemes, the transmitter provides all the coding gain in the position bit and essentially none of the coding gain in the sign bit. In order to improve the performance of the sign bit, receiver 400 includes the sign bit also in the trellis trace-back. This provides an improvement of about 1.5-2.0 dB in the performance of the system compared to a soft decision decoding receiver which only includes the PPM bits in its path memory (trace-back).

In the receiver 400 of the example embodiment of FIG. 4, no decisions are made in the matched filter/correlator 403. Rather, the correlator 403 generates all the relevant information for the demapper/decoder 406, including the correlation values and sign values. To this end, the matched filter calculates correlation values mₖ as given by Equation 2 for k=0, 1, 2, and 3. Moreover, the matched filter calculates the corresponding sign information, aₖ, derived from mₖ using the following equation:

aₖ=sign(mₖ) (5)

As is known, a soft metric is any metric that gives additional information about the bits for the decoder. With mapping defined as shown in Table 1, the soft metrics for bits b₁ and b₀ can be calculated from mₖ of eqn. 2 using Equations 6. In the example embodiments the soft metric are given by equations 6 and 7(a)-7(b):

mb₀₀=max(abs(m₀),abs(m₃))

mb₀₁=max(abs(m₁),abs(m₂))

mb₁₀=max(abs(m₀),abs(m₁))

mb₁₁=max(abs(m₂),abs(m₃)), (6)

where mb_{xy} represents the metric for bit x=y. From here, the soft metrics, sm₀ and sm₁, for bits b₀ and b₁, respectively, can be calculated as follows:

sm₀=mb₀₀−mb₀₁ (7a)

sm₁=mb₁₀−mb₁₁ (7b)

Soft metrics from either Equation 6 or Equations 7a-7b can be used to calculate the branch metrics in the Viterbi calculations.

In the present example embodiment, path metrics at the (i−1)^{th} node are denoted pmᵢ₋₁(s′) and those at the i^{th} node as pmᵢ(s), where s′ and s are the generic states at the (i−1)^{th} and i^{th} nodes respectively. The path metrics are calculated using the following equation:

$${pm}_{i} ( s ) = {min}_{{s}^{′}} [ {pm}_{i - 1} ( {s}^{′} ) + {bm}_{i} ( {s}^{′} , s ) ] \qquad ( 8 )$$

where bmᵢ(s′,s) is the branch metric for the branch from state s′ at node i−1 to state s at node i.

In an example embodiment, the trellis starts from state 0 so that:

$${pm}_{0} ( s ) = \begin{matrix}0 , s = 0 \\ ∞ , s \neq 0\end{matrix} \qquad ( 9 )$$

A path memory (of the decoder 406) at state s is updated with the state that contributed to the minimum path metric. In the decoder of the example embodiments, the path memory is updated with a survival sign/amplitude bit as well. The survival sign bit aids in determining the amplitude/sign bits at the end of trace-back length.

In an example embodiment, the survival sign bit is derived as follows:

Let ŝ be the survival state at state s, and bwᵢ(ŝ,s) be the branch output word for the state transition from ŝ to s. Using the mapping defined in Table 1, \hat{k} is derived from bwᵢ(ŝ,s)and the survival sign bit is determined from the set aₖ of Equation 5, with k=\hat{k}. The survival sign bit α_{\hat{k}} is then stored in the path memory of the state s along with the survival state ŝ.

After updating the path memories for all the states for node i, a trace-back sequence from the state that has a minimum metric is started (assuming the decoder is in steady state). The trace-back proceeds in a standard manner and at the end of the trace-back length, a decoded PPM bit 407 is output. Moreover, a sign/amplitude bit 408 is output that corresponds to the state at the end of the trace-back length. Thus, using the soft metrics of Equations 6, 7(a) and 7(b), the traceback may be carried out including sign/amplitude bits 408.

It is noted that the example embodiments do not increase the complexity of the receiver significantly when compared to known receivers. The storage of the sign bit in the path memory increases the memory size by (K*L) bits, where K is the number of states and L is the trace-back length. The logic for calculating α_{\hat{k}} also very minimal.

FIG. 6 shows a UWB network 600 in accordance with an example embodiment. The network includes an access point (AP) or host 601. The UWB network 600 is illustratively a wireless network 600 that includes a centralized MAC layer within the AP 601. Notably, the AP 601 operates according to one of the plurality of illustrative protocols referenced above. The AP 601 services a number of wireless stations STAs 602 according to the chosen protocol.

Illustratively, the network 600 is a WLAN, or wireless personal area network (WPAN), and the STAs (devices) 601, 602 are computers, mobile telephones, personal digital assistants (PDA), or similar devices that typically operate in such networks. As indicated by the two-way arrows, the devices 601, 602 may communicate bilaterally; and the host 601 and devices 602 may communicate bilaterally.

It is noted that according to certain MAC layer protocols, communication from one device of the STAs 602 to another of the STAs 602 is not necessarily direct; rather such communications pass through the host 601, which then transmits the communications (using known scheduling methods) to the correct recipient STA 602.

It is further noted that while only a few STAs 602 are shown, this is merely for simplicity of discussion. Clearly, many other devices 602 may be used. Finally, it is noted that the devices 602 are not necessarily the same. In fact a plethora of different devices that function under the chosen protocol(s) may be used within the network 600.

In keeping with the example embodiments described above, the transmitter for transmitting UWB pulses coded according to the example embodiments may be disposed in the AP 601 and the STAs 602. Moreover, the receiver 400 of the example embodiments described previously are included in the AP 601 and the STAs 602 of the network 600.

As can be appreciated from a review of the above-described example embodiments, benefits in the reliability of decoded data are realized. In known PPM/PAM systems, the PAM bits are decoded in the correlator, while the PPM bits are decoded in the convolutional decoder block. This results in unequal error performance for the PAM bits and the PPM bits. Contrastingly, in accordance with the example embodiments, the performance of the PAM bits is improved by including the PAM bits in the path memory of the trellis decoder and making a decision based on these bits along with the PPM bits after the trace-back. Illustratively, the receiver of the example embodiments provides a gain of approximately 1.5 dB to approximately 2.0 dB compared to a soft decision de-coding receiver for PPM bits.

In view of this disclosure it is noted that various methods and devices described in conjunction with a UWB system of the example embodiments can be implemented in hardware and software. Furthermore, the various methods, devices and parameters are included by way of example only and not in any limiting sense. In view of this disclosure, those skilled in the art can implement the various example devices and methods in determining their own techniques and needed equipment to effect these techniques, while remaining within the scope of the appended claims.

1. A data transmission and reception method, comprising: transmitting a plurality of position data bits and a plurality of amplitude data bits with each of the position data bits; and
decoding the position data bits and the amplitude data bits.

2. A data transmission method as recited in claim 1, wherein the data bits are modulated using pulse position modulation (PPM)/binary phase shift keying (BPSK) modulation technique and the amplitude data bits are sign bits.

3. The method of claim 1, wherein the method further comprises providing the amplitude data bits in a path memory of a trellis decoder and tracing back the amplitude data bits.

4. The method of claim 1, wherein the data transmission is an ultra-wide band (UWB) pulse transmission.

5. The method of claim 3, wherein the method further comprises calculating the soft metrics and using soft metrics to determine the position data bits.

6. The method of claim 5, wherein for a metric, mb_{xy}, for a bit where x=y, the soft metrics are sm₀ and sm₁ for bits b₀ and b₁, and are determined by:
sm₀=mb₀₀−mb_{01 sm}₁=mb₁₀−mb₁₁

7. The method of claim 6, wherein for an output, mₖ, of a correlator for a plurality of pulse positions, mb_{xy} is given by:
mb₀₀=max (abs (m₀), abs (m₃)) mb₀₁=max (abs (m₁), abs (m₂)) mb₁₀=max (abs (m₀), abs (m₁)) mb₁₁=max (abs (m₂), abs (m₃)).

8. A method as recited in claim 5, further comprising: calculating a survival amplitude bit for each of a plurality of nodes and each of a plurality of states and updating a path memory with the survival amplitude bits.

9. A method as recited in claim 8, wherein the decoding further comprises, after the updating, performing a trace-back sequence and outputting the amplitude bits and the position bits.

10. A method as recited in claim 9, wherein the amplitude bits and the position bits corresponds to a state having a minimum metric at an end of the trace-back sequence.

11. A method as recited in claim 10, wherein the amplitude data bits are derived from a sign, aₖ, of an output from a correlator and aₖ is given by:
aₖ=sign (mₖ)

12. An ultra-wide band (UWB) system (400), comprising:
a matched filter/correlator (403), which provides information on a plurality of position data bits and information on a plurality of amplitude data bits to a demapper/convolutional decoder (406), which decodes the position data bits and the amplitude data bits.

13. A UWB system as recited in claim 12, wherein the amplitude data bits are derived from a sign of a correlator output given by aₖ=sign (mₖ).

14. A UWB system as recited in claim 12, wherein the demapper/convolutional decoder 406 is a trellis decoder having a path memory.

15. A UWB system as recited in claim 14, wherein the trellis decoder 406 calculates soft metrics.

16. A UWB system as recited in claim 14, wherein the trellis decoder calculates a survival amplitude bit for each of a plurality of nodes and each of a plurality of states and updates the path memory with the survival amplitude bits.

17. A UWB system as recited in claim 14, wherein the trellis decoder updates the amplitude data bits and performs a trace-back sequence to output the amplitude data bits and with the position data bits.

18. A UWB system as recited in claim 16, wherein for a metric, mb_{xy}, for x=y the soft metrics are sm₀ and sm₁ for bits b₀ and b₁ are given by:
sm₀=mb₀₀−mb_{01 sm}₁=mb₁₀−mb₁₁

19. A UWB system as recited in claim 18, wherein for an output, mₖ, of the correlator for a plurality of different pulse positions, mb_{xy} is given by:
mb₀₀=max(abs (m₀),abs(m₃)) mb₀₁=max(abs(m₁l),abs(m₂)) mb₁₀=max(abs(m₀),abs(m₁)) mb₁₁=max(abs(m₂),abs(m₃)).

20. A UWB system as recited in claim 19, wherein the UWB system is a wireless network, including a plurality of wireless stations (STAs) and the STAs are one or more of computers, mobile telephones and personal digital assistants (PDA).
